(19) United States
(12) Patent Application Publication
(10) Pub. No.: US 2009/0321809 A1
(43) Pub. Date: Dec. 31, 2009

(54) GRADED OXY-NITRIDE TUNNEL BARRIER

(76) Inventors: Nirmal Ramaswamy, Boise, ID (US); Tejas Krishnamohan, Palo Alto, CA (US); Kyu Min, San Jose, CA (US); Thomas M. Graettinger, Boise, ID (US)

Correspondence Address: COOL PATENT, P.C.;c/o CPA Global, P.O. BOX 52050, MINNEAPOLIS, MN, 55402, US

(21) Appl. No.: 12/165,219

(22) Filed: Jun. 30, 2008

(51) Int. Cl. H01L 29/788; H01L 21/469

(52) U.S. Cl. 257/321; 438/761; 257/E29.129

(57) ABSTRACT

Briefly, a tunnel barrier for a non-volatile memory device comprising a graded oxy-nitride layer is disclosed.

### BACKGROUND

### TECHNICAL FIELD

The disclosure relates to the field of semiconductor manufacturing. In particular, the disclosure relates to tunnel barrier engineering in memory devices.

### BRIEF DESCRIPTION OF THE DRAWINGS

FIG. 1 is a sectional view of a particular embodiment of a non-volatile memory cell comprising a tunnel barrier comprising a graded oxy-nitride layer.

FIG. 2 is a sectional view of a particular embodiment of a tunnel barrier layer of a non-volatile memory cell comprising a graded oxy-nitride.

FIG. 3 is a sectional view of a particular embodiment of a non-volatile memory cell comprising a tunnel barrier having a graded oxy-nitride layer.

FIG. 4 is a block diagram illustrating a process for making a particular embodiment of a non-volatile memory cell comprising a tunnel barrier comprising a graded oxy-nitride.

FIG. 5 is a band diagram illustrating an evolution of tunnel barrier 102 comprising a graded nitride.

FIG. 6 is a graph illustrating nitrogen depth profiles for particular embodiments of a tunnel barrier layer comprising a graded oxy-nitride.

### DETAILED DESCRIPTION

In the following detailed description, numerous specific details are set forth in order to provide a thorough understanding of claimed subject matter. However, it will be understood by those skilled in the art that claimed subject matter may be practiced without these specific details. In other instances, well-known methods, procedures, and components have not been described in detail so as not to obscure claimed subject matter.

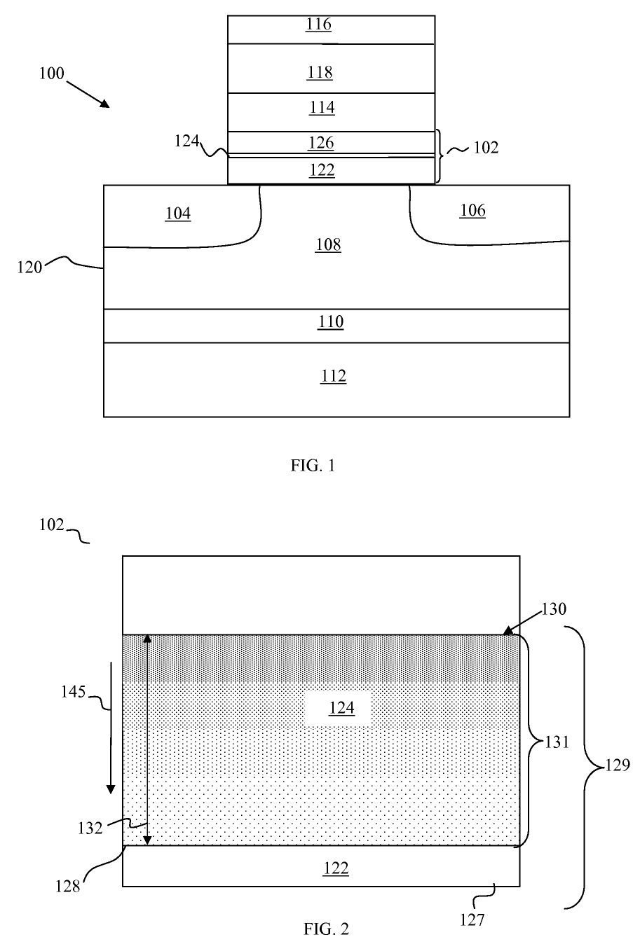

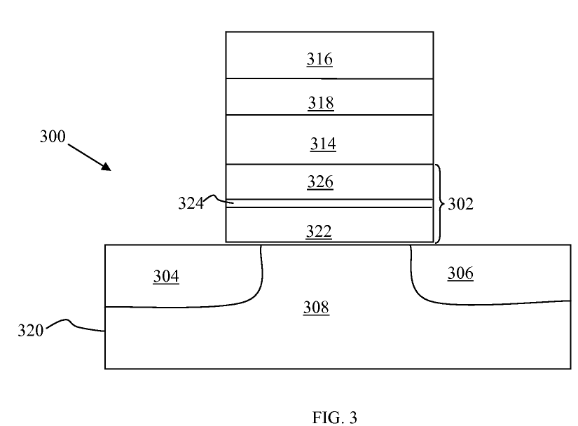

FIG. 1 illustrates a particular embodiment of a NAND flash Electrically Erasable Programmable Read-Only Memory (EEPROM) device 100 comprising a graded oxy-nitride tunnel barrier layer 102. In a particular embodiment, NAND flash device 100 may employ tunnel injection for writing and tunnel release for erasing. A graded oxy-nitride tunnel barrier layer 102 may enable improved voltage scaling for NAND flash device 100 program and/or erase functions. In another particular embodiment, tunnel barrier layer 102 may additionally enable improved hole erase voltage scaling for NAND flash devices comprising a charge trapping layer rather than a floating gate memory (see, for example, FIG. 3).

NAND flash device 100 may comprise substrate 120 having source 104, drain 106, P-well 108, deep N-well 110, and P-substrate 112 formed therein. According to a particular embodiment, substrate 120 may comprise a variety of materials such as silicon, gallium arsenide, silicon carbide, silicon germanium, germanium and/or polysilicon and claimed subject matter is not limited in this regard.

In a particular embodiment, NAND flash device 100 may additionally comprise floating gate 114 and control gate 1 16. According to a particular embodiment, device 100 may comprise layer 118 formed between floating gate 114 and control gate 1 16. Layer 118 may comprise a variety of materials, such as, for instance, oxide-nitride-oxide (ONO), hafnium oxide (HfOx), aluminum oxide (AlOx), zirconium oxide (ZrOx), zirconium aluminum oxide (ZrAlOx), hafnium aluminum oxide (HfAlOx) or hafnium oxide-aluminum oxide-hafnium oxide (HfOx-AlOx-HfOx), or combinations of these films and/or multi-layers incorporating these films. Floating gate 114 and control gate 116 may comprise any of a variety of materials known to those skilled in the art and may be formed by any of a variety of methods known to those skilled in the art and claimed subject matter is not limited in this regard.

According to a particular embodiment, NAND flash device 100 may further comprise tunnel barrier 102 formed between substrate 120 and floating gate 114. According to a particular embodiment, tunnel barrier 102 may comprise first barrier layer 122, graded oxy-nitride layer 124 and second barrier layer 126. Tunnel barrier 102 may provide charge transport for either through tunneling or hot carrier injection. According to a particular embodiment, graded oxy-nitride layer 124 may comprise a nitrogen gradient extending between first barrier layer 122 and second barrier layer 126 as is explained in greater detail with respect to FIG. 2.

FIG. 2 illustrates a particular embodiment of tunnel barrier 102. Tunnel barrier 102 may comprise foundation layer 129 extending from plane 127 to plane 130. In a particular embodiment, foundation layer 129 may comprise first barrier layer 122 and graded oxy-nitride layer 124. In a particular embodiment, second barrier layer 126 may be disposed over oxy-nitride layer 124. In a particular embodiment, foundation layer 129 may be formed over substrate 108 (see FIG. 1) and may comprise a variety of materials such as silicon dioxide (SiO2), aluminum oxide (AlOx), hafnium silicon oxide (HfSiOx), Hafnium oxide (HfOx), aluminum silicon oxide (AlSiOx), ZrOx and/or zirconium silicon oxide (ZrSiOx) and claimed subject matter is not limited in this regard.

In a particular embodiment, graded oxy-nitride layer 124 may be formed by nitriding portion 131 of foundation layer 129 from plane 130 to plane 128 thus forming first barrier layer 122 and graded oxy-nitride layer 124. Controlling nitriding conditions may enable forming a nitrogen gradient in oxy-nitride layer 124 having a concentration that generally increases from plane 128 to plane 130. Wherein the area of lowest concentration of nitrogen may be at or near plane 128 and may vary over graded oxy-nitride layer 124 to an area of greatest nitrogen concentration at or near plane 130. Formation of graded oxy-nitride layer 124 within foundation layer 129 may enable formation of foundation layer 129 to greater thicknesses than in conventional methods thus enabling improved control of the thickness of first barrier layer 122.

As is shown in FIG. 2 by arrow 145, nitrogen concentration decreases with increasing depth into oxy-nitride layer 124 with respect to plane 130. According to a particular embodiment, graded oxy-nitride layer 124 may be formed by a variety of methods such as decoupled plasma nitridation (DPN) and/or nitriding by annealing in ambient of ammonia (NH₃), nitrogen (N₂), nitric oxide (NO) and/or nitrous oxide (N₂O) or combinations thereof and claimed subject matter is not limited in this regard.

In a particular embodiment, where graded oxy-nitride layer 124 is formed by decoupled plasma nitridation (DPN) of foundation layer 129 at plane 130 and where foundation layer 129 comprises silicon dioxide (SiO2), DPN at plane 130 may form an oxy-nitride layer 124 comprising silicon oxy-nitride (SiON) having a nitrogen concentration gradient. However this is merely an example of an oxy-nitride layer that may be formed by DPN where a foundation layer comprises SiO₂ and claimed subject matter is not limited in this regard.

According to a particular embodiment, nitrogen may be incorporated to a depth D 132 into foundation layer 129 to form oxy-nitride layer 124. Depth D 132 may be about 1 to 50 Å as measured from plane 130. However, this is merely an example of a method of forming a graded oxy-nitride layer to a particular depth and claimed subject matter is not limited in this regard.

In a particular embodiment, a concentration of nitrogen may be varied from 0-80 atomic percent as measured over depth D 132 of oxy-nitride layer 124. In a particular embodiment, such a nitrogen gradient may begin at a depth of between about 1 to 50 Å below plane 130. Such a nitrogen concentration may generally increase from plane 128 to plane 130. However, this is merely an example of a particular embodiment of a nitrogen gradient of a graded oxy-nitride layer and claimed subject matter is not limited in this regard.

According to a particular embodiment, second barrier layer 126 may be formed over graded nitride layer 124. In a particular embodiment, second barrier layer 126 may be formed by a variety of methods known to those skilled in the art (for example, various deposition techniques and/or growth techniques may be used). Second barrier layer 126 may comprise a variety of materials such as silicon nitride and/or silicon dioxide and claimed subject matter is not limited in this regard. In a particular embodiment, second layer 126 may also be formed by depositing a silicon nitride layer and subsequent conversion of silicon nitride to silicon dioxide by oxidation.

FIG. 3 illustrates another particular embodiment of a NAND flash device 300 comprising a graded oxy-nitride tunnel barrier layer 302. In a particular embodiment, tunnel barrier layer 302 may enable improved hole erase voltage scaling for NAND flash devices comprising a charge trapping layer 314 rather than a floating gate memory as illustrate in FIG. 1.

According to a particular embodiment, NAND flash device 300 may comprise a variety of materials such as a metal-insulator-nitride-oxide-silicon MINOS system and claimed subject matter is not limited in this regard. In a particular embodiment, charge trapping layer 314 may comprise a variety of materials, such as, for instance, a variety of high-k dielectrics, nano-dot material, nitride, silicon nitride, hafnium oxide (HfOx), aluminum oxide (AlOx), zirconium oxide (ZrOx), zirconium aluminum oxide (ZrAlOx), hafnium aluminum oxide (HfAlOx), lanthanum oxide (LaOx) or hafnium oxide-aluminum oxide-hafnium oxide (HfOx-AlOx-HfOx), or combinations thereof. Additionally, NAND flash device 300 may comprise substrate 320 having source 304, drain 306 and P-well 308 formed therein. In a particular embodiment, NAND flash device 300 may additionally comprise blocking oxide 318 and control gate 316. However, this is merely an example of an embodiment of a NAND flash device assembly comprising a charge trapping layer and claimed subject matter is not limited in this regard.

According to a particular embodiment, device 300 may further comprise tunnel barrier layer 302 formed between substrate 320 and charge trapping layer 314. According to a particular embodiment, tunnel barrier 302 may comprise first barrier layer 322, graded oxy-nitride layer 324 and second barrier layer 326. According to a particular embodiment, graded oxy-nitride layer 324 may comprise a nitride gradient extending between first barrier layer 322 and second barrier layer 326.

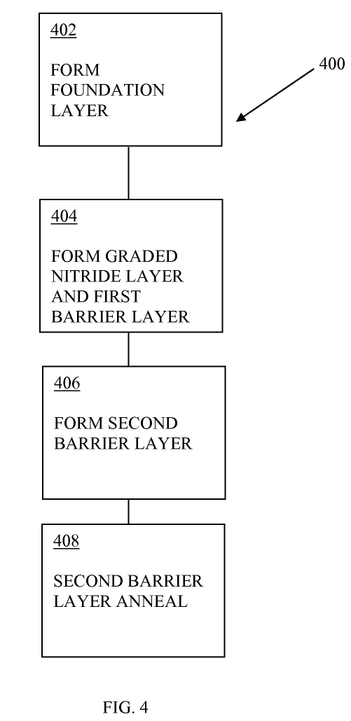

FIG. 4 is a block diagram illustrating a particular embodiment of process 400 for forming a tunnel barrier in a memory cell comprising a graded oxy-nitride, the tunnel barrier formed over a substrate material. In a particular embodiment, the process may begin at block 402 where a foundation layer may be formed. Such a foundation layer may comprise a variety of materials such as for instance silicon dioxide (SiO2), aluminum oxide (AlOx), hafnium silicon oxide (HfSiOx), aluminum silicon oxide (AlSiOx), ZrOx and/or zirconium silicon oxide (ZrSiOx) and claimed subject matter is not limited in this regard.

In a particular embodiment, process 400 may flow to block 404 where a graded nitride layer may be formed in a foundation layer by nitriding a surface of the foundation layer. As previously discussed, graded nitride layer 124 may be formed by various methods such as DPN and/or annealing in ambient of ammonia (NH₃), nitrogen (N₂), nitric oxide (NO) and/or nitrous oxide (N₂O). Such nitriding may form a graded oxy-nitride layer within a portion of previously formed foundation layer converting the foundation layer to a first barrier layer and an oxy-nitride layer.

In a particular embodiment, where a foundation layer comprises SiO₂ a graded oxy-nitride layer as formed in a foundation layer may comprise silicon oxy-nitride (SiON). In other particular embodiments, where a foundation layer may comprise; aluminum oxide (AlOx), hafnium silicon oxide (HfSiOx), aluminum silicon oxide (AlSiOx), zirconium oxide (ZrOx) and/or zirconium silicon oxide (ZrSiOx) a graded oxy-nitride layer may comprise; silicon oxy-nitride (SiON), aluminum oxy-nitride (AlON), hafnium silicon oxy-nitride (HfSiON), aluminum silicon oxy-nitride (AlSiON), zirconium oxy-nitride (ZrON) and/or zirconium silicon oxy-nitride (ZrSiON), respectively and claimed subject matter is not limited in this regard.

In a particular embodiment, at block 404 a graded oxy-nitride layer may be formed such that nitrogen may be incorporated to a depth of about 1 Å to 50 Å from a surface of a foundation layer (see foundation layer 129 and depth indicator 132 of FIG. 2). In a particular embodiment, where nitriding is performed by DPN, a nitrogen concentration gradient may be substantially controlled and may be a function of power applied during DPN and time of DPN application.

Table 1 below provides example DPN powers and times and average nitrogen concentrations of an oxy-nitride layer for a number of samples to show how nitrogen concentration may be a function of DPN power and time.

TABLE 1

| | | | Average Surface |
|---|---|---|---|
| Sample | Power (W) | Time (s) | Concentrations (atomic %) N |
| 1 | 200 | 150 | 4.1 |
| 2 | 400 | 30 | 7.9 |
| 3 | 800 | 60 | 12.5 |
| 4 | 1420 | 62 | 14.8 |
| 5 | 2050 | 90 | 18.4 |
| 6 | 2050 | 180 | 20.7 |

Referring again to FIG. 4, in a particular embodiment, process 400 may flow to block 406 where a second barrier layer may be formed over an oxy-nitride layer. Such a second barrier layer may be formed by a variety of processes known to those skilled in the art. For example, a second barrier layer may be formed by various deposition techniques and/or growth techniques. In a particular embodiment, a second barrier layer may also be formed by depositing a silicon nitride layer and subsequent conversion of silicon nitride to silicon dioxide by oxidation and claimed subject matter is not limited in this regard. According to a particular embodiment, a second barrier layer may comprise a variety of materials such as silicon nitride and/or silicon dioxide and claimed subject matter is not limited in this regard.

In a particular embodiment, process 400 may flow to block 408 where a second barrier layer anneal may occur. Such a second barrier layer anneal may be performed by a variety of methods such as a high temperature and/or nitrogen or oxygen anneal to heal defects in the second layer and improve the quality of the second barrier layer oxide.

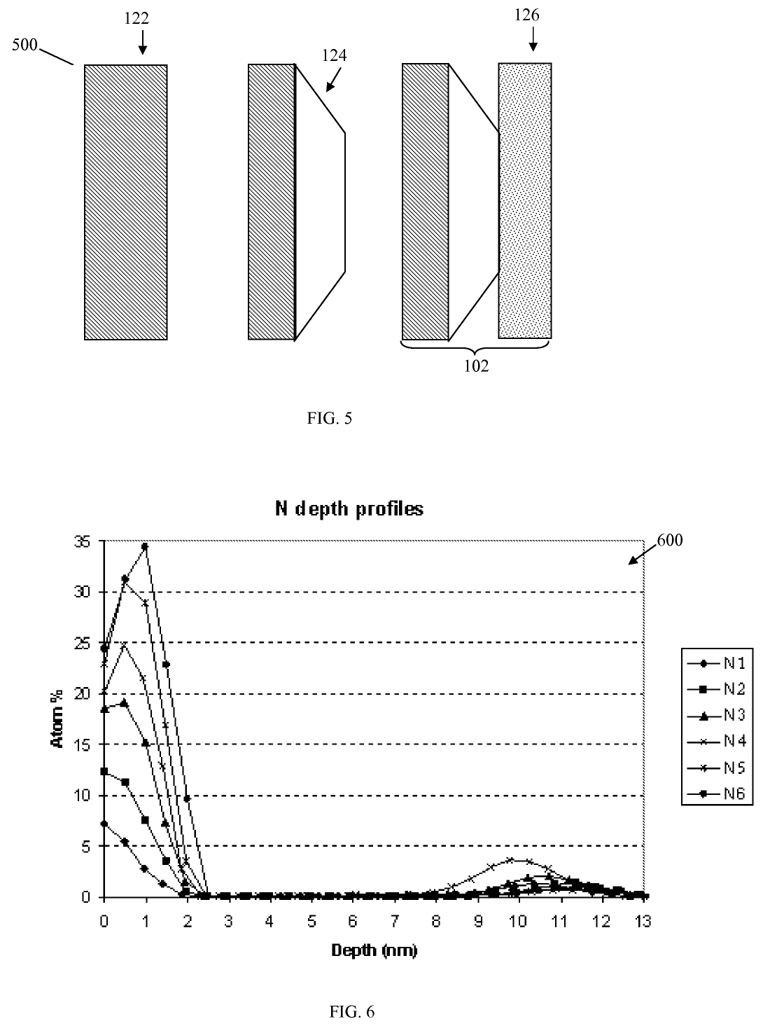

FIG. 5 is a band gap diagram 500 illustrating a formation of tunnel barrier 102 comprising a graded oxy-nitride wherein as the concentration of nitrogen in oxy-nitride layer band 124 increases band gap decreases as exemplified by the trapezoidal shape of oxy-nitride layer band 124. In a particular embodiment, varying nitrogen concentration may enable tailoring a band structure in a memory cell. According to a particular embodiment, tailoring a band structure may enable improving program and/or erase voltages without incurring substantial loss of read disturb or retention margins. As can be seen in FIG. 5, a nitrogen concentration of graded oxy-nitride layer 124 may increase from first barrier layer 122 as oxy-nitride layer 124 approaches second barrier layer 126.

FIG. 6 is a graph 600 illustrating six nitrogen depth profiles for particular embodiments of a tunnel barrier layer comprising a graded oxy-nitride. Graded oxy-nitride layers of samples N1-N6 were formed by DPN. As noted in Table 1 above, during DPN, samples N1-N6 were exposed to varied power levels for various lengths of time.

Graph 600 shows the variation in nitrogen concentration with respect to depth as measured through a thickness of oxy-nitride layer 124 (as shown in FIG. 2) from plane 130 to plane 128 for samples N1-N6. As can be seen from graph 600 nitrogen concentrations generally decrease with depth. As is demonstrated in graph 600 variations in concentration of nitrogen in particular embodiments of a tunnel barrier comprising a graded oxy-nitride generally tend to decrease with increasing depth, however, nitrogen concentrations may not decrease linearly. These are merely examples of particular embodiments of nitrogen gradients in tunnel barrier layers and claimed subject matter is not so limited.

While certain features of claimed subject matter have been illustrated as described herein, many modifications, substitutions, changes and equivalents will now occur to those skilled in the art. It is, therefore, to be understood that the appended claims are intended to cover all such embodiments and changes as fall within the spirit of claimed subject matter.

What is claimed is:

1. An apparatus comprising:
a substrate;
a foundation layer formed on the substrate, the foundation layer comprising;
an oxy-nitride layer formed in a portion of the foundation layer wherein the oxy-nitride layer comprises a nitrogen gradient, wherein a nitrogen concentration of the nitrogen gradient tends to decrease as depth increases into a thickness of the oxy-nitride layer; and
a first barrier layer wherein the first barrier layer comprises a remaining portion of the foundation layer where there is substantially no nitrogen gradient; and
a second barrier layer formed over the oxy-nitride layer.

2. The apparatus of claim 1 wherein the first barrier layer, the second barrier layer and the oxy-nitride comprise a tunnel barrier layer of a NAND flash memory cell comprising a floating gate.

3. The apparatus of claim 1 wherein the first barrier layer, the second barrier layer and the oxy-nitride comprise a tunnel barrier layer of a NAND flash memory cell comprising a charge trapping layer.

4. The apparatus of claim 3 wherein the charge trapping layer comprises nano-dot material, nitride (N2), oxy-nitride (NO), hafnium oxide (HfOx), aluminum oxide (AlOx), zirconium oxide (ZrOx), zirconium aluminum oxide (ZrAlOx), hafnium aluminum oxide (HfAlOx), lanthanum oxide (LaOx) or hafnium oxide-aluminum oxide-hafnium oxide (HfOx-AlOx-HfOx), or combinations thereof.

5. The apparatus of claim 3 wherein the NAND flash memory cell comprises a metal-insulator-nitride-oxide-silicon (MINOS).

6. The apparatus of claim 1 wherein the foundation layer comprises silicon dioxide (SiO2), aluminum oxide (AlOx), hafnium silicon oxide (HfSiOx), aluminum silicon oxide (AlSiOx), zirconium oxide (ZrOx) or zirconium silicon oxide (ZrSiOx), or combinations thereof.

7. The apparatus of claim 1 wherein the oxy-nitride layer comprises silicon oxy-nitride (SiON), aluminum oxy-nitride (AlON), hafnium silicon oxy-nitride (HfSiON), aluminum silicon oxy-nitride (AlSiON), zirconium oxy-nitride (ZrON) or zirconium silicon oxy-nitride (ZrSiON), or combinations thereof.

8. The apparatus of claim 1 wherein the nitrogen concentration of the nitrogen gradient ranges from about 0 atomic percent to about 80 atomic percent.

9. The apparatus of claim 1 wherein the nitrogen gradient of the oxy-nitride layer begins at a depth of between about 1 Å to 50 Å below an interface between the oxy-nitride layer and the second barrier layer.

10. A method of forming a tunnel barrier in a non-volatile memory cell comprising:
forming a foundation layer over a substrate;
nitriding a surface of the foundation layer to form an oxy-nitride layer in a portion of the foundation layer wherein a remaining portion of the foundation layer comprising substantially no nitrogen gradient comprises a first barrier layer; and
forming a second barrier layer over the oxy-nitride layer;
wherein the oxy-nitride layer comprises a nitrogen gradient, wherein a nitrogen concentration of the graded oxy-nitride layer generally decreases with increasing depth into a thickness of the oxy-nitride layer with respect to an interface between the oxy-nitride layer and the second barrier layer.

11. The method of claim 10 wherein nitriding the surface of the foundation layer to form the oxy-nitride layer further comprises nitriding of the foundation layer via decoupled plasma nitridation (DPN).

12. The method of claim 10 wherein nitriding the surface of the foundation layer to form the oxy-nitride layer further comprises annealing the foundation layer.

13. The method of claim 12 wherein annealing the foundation layer further comprises exposing the foundation layer to ambient of ammonia (NH₃), nitrogen (N₂), nitric oxide (NO) or nitrous oxide (N₂O), or combinations thereof.

14. The method of claim 10 wherein nitriding the surface of the foundation layer to form the oxy-nitride layer further comprises nitriding of the foundation layer to a depth of about 1 Å to about 50 Å into the foundation layer measured from the surface of the foundation layer.

15. The method of claim 10 further comprising annealing the second barrier layer.
